(19) United States
(12) Patent Application Publication
(10) Pub. No.: US 2009/0072870 A1
(43) Pub. Date: Mar. 19, 2009

(54) DIGITAL SIGNAL PROCESSING CIRCUIT

(75) Inventor: Hirofumi Inada, Kyoto (JP)

Correspondence Address: CANTOR COLBURN, LLP, 20 Church Street, 22nd Floor, Hartford, CT, 06103, US

(73) Assignee: ROHM CO., LTD., Kyoto (JP)

(21) Appl. No.: 11/959,628

(22) Filed: Dec. 19, 2007

(30) Foreign Application Priority Data
Dec. 27, 2006 (JP) 2006-353145

(51) Int. Cl. H03B 19/10

(52) U.S. Cl. 327/119

(57) ABSTRACT

A digital signal processing circuit performs a predetermined computation processing on input data sequentially input at a first frequency, and generates output data of a second frequency oversampled to n times (n is an integer greater than or equal to 2). A computation processing unit collectively computes m (m is 2≦m≦n) successive output data in output data at n sampling timings after oversampling. A data holding unit holds data at a predetermined sampling timing in the data generated in the computation processing unit. An output data holding unit holds data at m sampling timings to be output. An output data generating unit sequentially outputs m output data obtained by the computation processing unit according to a second frequency.

### BACKGROUND OF THE INVENTION

1. Field of the Invention

The present invention relates to digital signal processing.

2. Description of the Related Art

A predetermined signal processing is desirably performed on certain digital data to generate oversampled data. Such signal processing will be reviewed with αΣ modulation by way of example. FIG. 1 is a circuit configuration example for generating a bit stream which is αΣ-modulated and oversampled to n times.

A αΣ modulator 500 of FIG. 1 includes an oversampling circuit 501, flip-flops FF1 to FF3, adders ADD1 to ADD3, and multiplexers MUX1 to MUX3. Input data din is assumed to be input in synchronization with a first clock signal CK1. The oversampling circuit 501, which is input with a clock signal clk having a second frequency f2 of n times a first frequency f1, oversamples the input data dx and outputs the data at the second frequency f2. A plurality of oversampled input data din corresponding to certain input data dx takes the same value.

The configuration of the αΣ modulator is generally known, and thus will only be briefly described herein.

The adder ADD1, flip-flop FF1, and multiplexer MUX1 constitute one unit circuit. The adder ADD1 adds the data din from the previous stage, the data from the multiplexer MUX1, and the output data of the flip-flop FF1. The addition result of the adder ADD1 is input to a D terminal (input terminal) of the flip-flop FF1. The high frequency clock signal clk of the second frequency f2 is input to a clock terminal of the flip-flop FF1. Predetermined constants +a1, −a1 are input to the multiplexer MUX1.

A set of adder ADD2, flip-flop FF2, and multiplexer MUX2 and a set of adder ADD3, flip-flop FF3, and multiplexer MUX3 also have the same configuration, and thus three unit circuits are cascade-connected. In the circuit of FIG. 1, a bus width (number of bits) of a data line is designed to become larger towards the post-stage to suppress overflow.

A MSB (most significant bit) of the output data int3out of the flip-flop FF3 at the final stage is output as the bit stream data. The multiplexer MUX switches the value of the constant to be output to the adder ADD according to the MSB of the past output data int3out. According to the αΣ modulator 500 of FIG. 1, the data is updated for every positive edge of the high frequency clock clk, and the αΣ-modulated bit stream is generated in synchronization with the high frequency clock clk.

[Patent document 1] Japanese Patent Application Laid-Open No. 2005-151184

The flip-flop performs a latch operation. When the first frequency f1 is 15 MHz and the oversampling rate is n=10 times, the second frequency f2 of the high frequency clock clk becomes 150 MHz, and the power consumption increases.

### SUMMARY OF THE INVENTION

The present invention has been achieved in view of the above problem, the general purpose of the present invention is to reduce the power consumption of the circuit.

A digital signal processing circuit of one embodiment of the present invention relates to a digital signal processing circuit which performs a predetermined computation processing on input data sequentially input at a first frequency, and generates output data of a second frequency oversampled to n times (n is an integer greater than or equal to 2). The digital signal processing circuit includes a computation processing unit which collectively computes m (m is 2≦m≦n) successive output data in the output data at n sampling timings after oversampling; a data holding unit which holds data at a predetermined sampling timing in the data generated in the computation processing unit; and a data output unit which sequentially outputs the m output data obtained by the computation processing unit according to a second frequency. The computation processing unit generates m successive output data after the predetermined sampling timing based on the data at the predetermined sampling timing held in the data holding unit and the input data.

The phrase “collectively compute” refers to performing computation without performing latching in the middle of the computation or holding of data by the flip-flop.

According to such embodiment, the computation processing unit can be operated at the frequency of n/m times the first frequency instead of the frequency of n times the first frequency by collectively performing the computation processing on the m data. As a result, the power consumption of the circuit can be thereby decreased.

Here, m may be a divisor of n. In this case, the data at n sampling timings after oversampling can be generated at exactly m/n computations.

The data holding Unit may include a flip-flop input with a clock signal having a frequency of n/m times the first frequency. In the specification, the flip-flop includes latch circuits such as D latch in addition to D flip-flop, JK flip-flop, and RS flip-flop.

The computation processing circuit may include m cascade-connected computation units. An i^{th} (i≠1) computation unit may perform computation processing using data generated by an i−1^{th} computation unit, and a first computation unit performs computation processing using the data held in the data holding unit. The data holding unit may hold the data generated by an m^{th} computation unit.

The data output unit may include an output data holding unit which holds successive data worth (n/m) times of the output data at the m successive sampling timings generated from the m computation units when m≠n, and sequentially output the data held in the output data holding unit according to the second frequency.

The predetermined computation process may be a αΣ modulation.

The digital signal processing circuit according to one embodiment may be monolithically integrated on one semiconductor substrate. The term “monolithically integrated” includes a case where all the components of the circuit are formed on a semiconductor substrate or a case where the main components of the circuit are monolithically integrated, where some resistor or capacitor may be arranged outside the semiconductor substrate to adjust the circuit constant. The circuit area can be reduced. by integrating the circuit components as one IC.

Another embodiment of the present invention relates to electronic equipment. The electronic equipment includes a battery; and the digital signal processing circuit described above which receives power supply from the battery.

According to such embodiment, the battery usage time can be extended since the power consumption of the digital signal processing circuit component can be reduced.

Another further embodiment relates to a αΣ modulator which αΣ-modulates input data sequentially input at a first frequency and generates output data of a second frequency oversampled to n times (n is an integer greater than or equal to 2). The αΣ modulator includes m cascade-connected αΣ modulation units which respectively generate m (m is 2≦m≦n) successive output data in the output data at n sampling timings after oversampling; and a data holding unit which holds data generated by the m^{th} αΣ modulation unit. An i^{th} (i≠1) αΣ nodulation unit generates data based on data generated by an i−1^{th} αΣ modulation unit and a most significant bit of the output data generated by the i−1^{th} αΣ modulation unit; and a first αΣ modulation unit generates data based on the data held in the data holding unit.

According to such embodiment, it can be operated at the frequency of n/m times the first frequency instead of the frequency of n times the first frequency by collectively generating the output data at m sampling timings by m αΣ modulation units. As a result, the power consumption of the circuit can be thereby reduced.

The αΣ modulation unit may include cascade-connected sub-circuits of L number corresponding to an order of the αΣ modulation. The sub-circuit of j^{th} stage arranged in the i^{th} αΣ modulation unit may include a multiplexer which outputs a predetermined value corresponding to the most significant bit of the output data of the i−1^{th} (m^{th} when i=1) αΣ modulation unit, and an adder which adds the output data of the sub-circuit of j−1^{th} stage (the input data when j=1), the output data of the sub-circuit of the j^{th} stage in the i−1^{th} (m^{th} when i=1) αΣ modulation unit, and the output data of the multiplexer. The output data of the adder of the sub-circuit of j(≠L)^{th} stage is input to the adder of the sub-circuit of j+1^{th} stage, and the output of the adder of the sub-circuit of j(=L)^{th} stage may be the output data of the i^{th} αΣ modulation unit. The data holding unit may hold the output data of each sub-circuit contained in the m^{th} αΣ modulation unit.

The data holding unit may include a flip-flop input with a clock signal having a frequency of n/m times the first frequency.

The αΣ modulator of the embodiment may be monolithically integrated on one semiconductor substrate.

still another embodiment of the present invention relates to electronic equipment. The electronic circuit includes a battery; and the αΣ modulator described above which receives power supply from the battery.

According to such embodiment, the battery usage time can be extended since the power consumption of the αΣ modulator can be reduced.

It is to be noted that any arbitrary combination or rearrangement of the above-described structural components and so forth is effective as and encompassed by the present embodiments.

Moreover, this summary of the invention does not necessarily describe all necessary features so that the invention may also be a sub-combination of these described features.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a circuit configuration example for generating a bit stream which is αΣ-modulated and oversampled to n times;

FIGS. 2A and 2B are block diagrams showing a configuration of a digital signal processing circuit according to an embodiment of the present intention;

FIG. 3 is a circuit diagram showing an application example of the digital signal processing circuit of FIG. 1, and is a circuit diagram showing a configuration of a αΣ modulator according to the embodiment;

FIGS. 4A and 4B are timing charts showing operation states of the αΣ modulators of FIG. 3 and FIG. 1, respectively;

FIG. 5 is a circuit diagram showing a configuration of electronic equipment using the Σα modulator of FIG. 3; and

FIG. 6 is a block diagram showing an inner configuration of an analog front end circuit and a baseband circuit of FIG. 5.

### DETAILED DESCRIPTION OF THE PREFERRED EMBODIMENTS

The invention will now be described based on preferred embodiments which are not intended to limit the scope of the present invention but merely exemplify the invention. All of the features and the combinations thereof described in the embodiment are not necessarily essential to the invention.

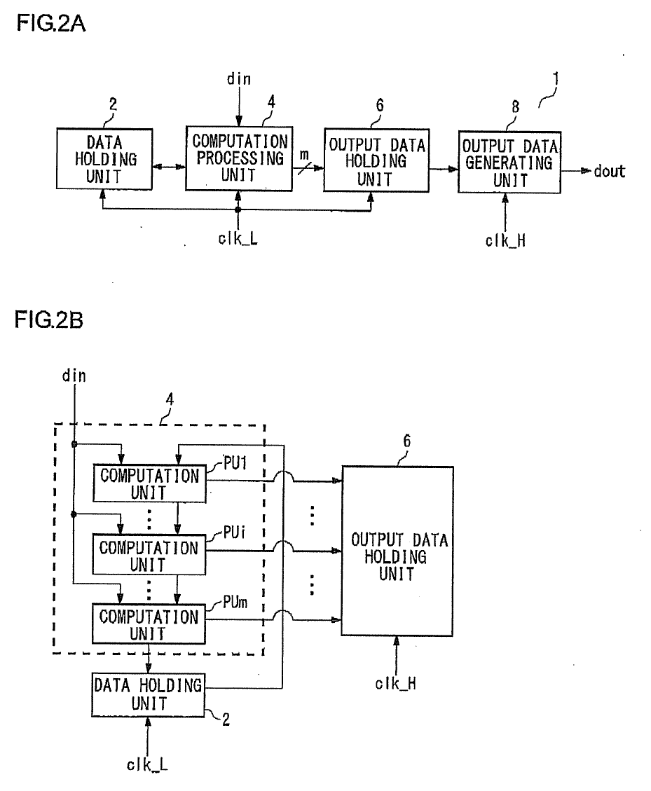

FIGS. 2A and 2B are block diagrams showing a configuration of a digital signal processing circuit 1 according to an embodiment of the present invention. The digital signal processing circuit 1 performs a predetermined computation processing on the input data din sequentially input at a first frequency f1 to generate output data dout of a second frequency f2 (f2=f1×n) oversampled to n times (n is an integer greater than or equal to 2, and hereinafter assumed as ten times). That is, the output data dout corresponding to n (=10) sampling timings are generated with respect to one input data din.

The digital signal processing circuit 1 of FIG. 2A includes a data holding unit 2, a computation processing unit 4, an output data holding unit 6, and an output data generating unit 8.

At least two clock signals clk_L, clk_H are provided to the digital signal processing circuit 1. The clock signal clk_H has the second frequency f2 after oversampling. The clock signal clk_L has a frequency of the same extent as the input data din.

The computation processing unit 4 collectively computes m (m is 2≦m≦n) successive output data dout in n (worth n samplings) output data dout based on the data held in the data holding unit 2. Preferably, m is a divisor of n. In the case of oversampling of ten times (n=10), m is set to be 10, 5, or 2.

The data holding unit 2 is a circuit which holds data at a predetermined sampling timing in the data generated in the computation processing unit 4, and is configured using flip-flop, latch circuit, and the like. The data holding unit 2 latches the data according to the clock signal clk_L. That is, the frequency the latch operation is executed is set lower than the frequency of the clock signal clk_H.

The computation processing unit 4 generates m successive output data after the predetermined sampling timing based on the data at the predetermined sampling timing held in the data holding unit 2, and the input data din.

When n=m, the computation processing unit 4 generates the data for all the sampling points in one computation processing. When n=10 and m=5, the computation processing unit 4 generates the data for all the sampling points in two computation processings.

The computation processing unit 4 performs computation by dividing the data for all the sampling timings to n/m times. Since the latch operation is necessary for every computation, the frequency of the clock signal clk_L is set according to the values of n and m. The frequency is preferably set to clk_L=f1×n/m.

The output data holding unit 6 holds m output data obtained by the computation processing unit 4. The output data generating unit 8 uses the second clock signal clk2 of the second frequency f2 to sequentially output the data held in the output data holding unit 6 at the second frequency f2(=f1×n).

A case of performing the oversampling process will be considered in the digital signal processing. In this case, the original data is sometimes used as it is without performing linear interpolation or zero interpolation for the data at the sampling timing to be interpolated. In such case, the oversampled data is generated, and the predetermined signal processing is executed on the data after oversampling, whereby signal processing in the second frequency f2 becomes necessary, the operation speed of the circuit rises, and the power consumption increases.

The digital signal processing circuit 1 according to the present embodiment, however, uses the feature that the data before oversampling is continuously used for the n data after oversampling. That is, the data at the m successive sampling timings are collectively generated using the data before oversampling.

When the data d1 at time t0 and the data d2 at time t1 are oversampled, the data at the intermediate sampling timing all become d1. Therefore, if data d1 is input at time t0, the data at subsequently sampling timing can be computed. In such case, the computation processing is performed at the clock signal of low frequency according to the digital signal processing circuit 1 of the present embodiment, and thus the power consumption of the circuit can be reduced.

In other words, according to the digital signal processing circuit 1 of FIG. 2A, the data at m sampling timing are collectively computed, and thus n/m computation merely needs to be performed on one data input. The power consumption of the circuit is thus reduced.

When the value of m is large, the circuit area obviously increases, but the clock frequency necessary for the computation processing can be lowered, and thus the effect of reducing the power consumption enhances. When the value of m is small, the increase in circuit area can be suppressed. Therefore, the value of m is determined in view of the balance between the circuit area and the reduction in power consumption.

FIG. 2B is a block diagram showing a configuration example of the computation processing unit 4. The computation processing unit 4 may include m computation units PUl to PUm, which are cascade-connected. The i^{th} (i≠1) computation unit PUi performs the computation processing using at least the data generated by the i−1^{th} computation unit. The first computation unit performs the computation processing using at least the data held in the data holding unit 2. The data holding unit 2 holds the data generated by the m^{th} computation unit PUm. The output data at the i^{th} sampling timing computed by the i^{th} computation unit PUi is latched by the output data holding unit 6.

According to the configuration of FIG. 2B, even when a process requiring data at the past sampling timing Tj (j<i) is performed to generate the output data at a certain sampling timing Ti upon handling a time-series data, collective execution can be performed.

FIG. 2B shows a case where the data at the sampling timing Ti-1 one before is required to generate the output data at a certain sampling timing Ti is shown. When the data at sampling timings Tj (j≦i−2) two or more before are required, the data of the computation unit Puj is input to the computation unit PUi.

An application example to a specific circuit of the digital signal processing circuit 1 of FIGS. 2A and 2B will now be described.

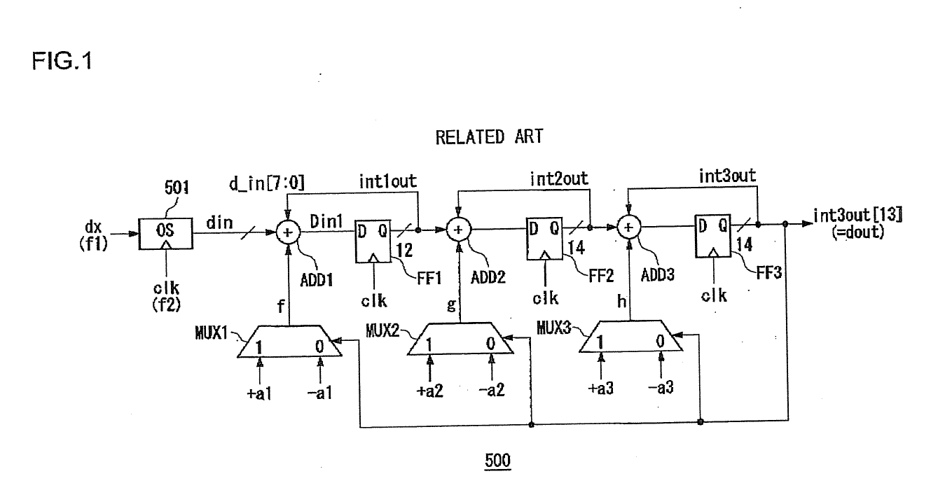

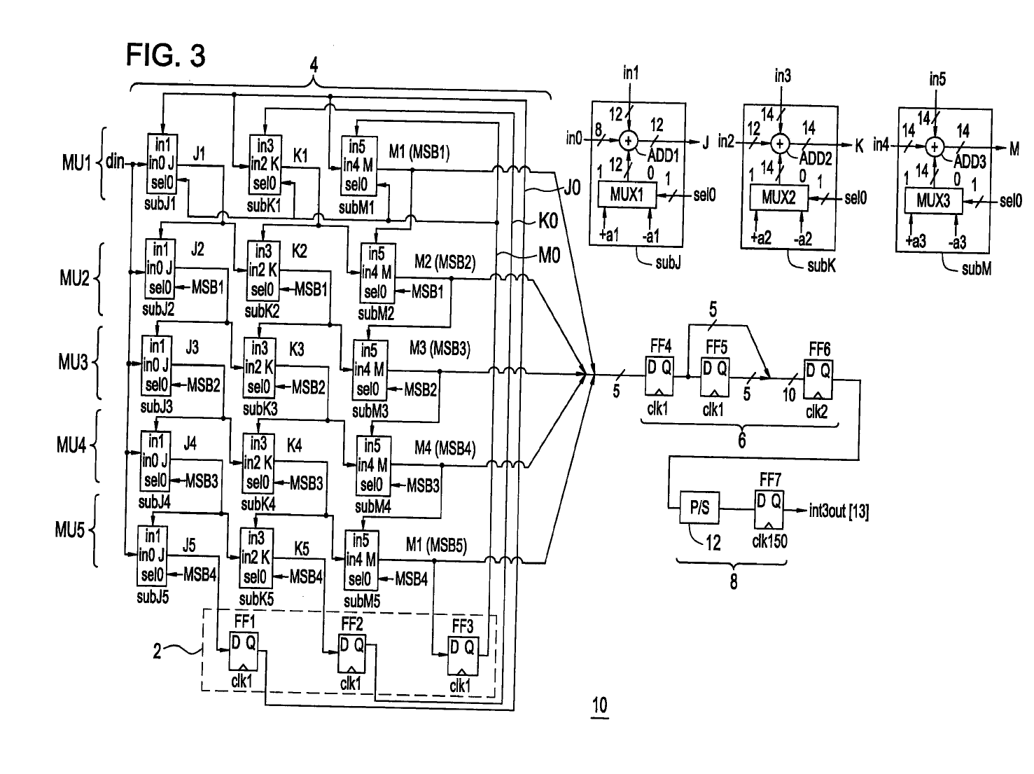

FIG. 3 is a circuit diagram showing an application example of the digital signal processing circuit of FIG. 1, and is a circuit diagram showing a configuration of a αΣ modulator 10 according to the embodiment. The αΣ modulator 10 is preferably integrated on one semiconductor substrate as a functional TC. The αΣ modulator 10 of FIG. 3 is a circuit which executes functions similar to the αΣ modulator of FIG. 1. The αΣ modulator 10 αΣ-modulates the input data din sequentially input at the first frequency f1, and generates the output data of the second frequency f2 oversampled to n times (n is an integer greater than or equal to 2, hereinafter assumed as n=10).

The αΣ modulator 10 of FIG. 3 includes m (m is 2≦m≦n) cascade-connected αΣ modulation units MUl to Mum (m=5 in the present embodiment), the data holding unit 2, the output data holding unit 6 which holds output data MSB1 to MSB5 generated from each αΣ modulation unit MU1 to MU5, and the output data generating unit 8.

The αΣ modulation units MU1 to MU5 respectively generates m (=5) successive output data MSB1 to MSB5 in the output data at n (=10) sampling timings after oversampling. The αΣ modulation units MU1 to MU5 correspond to the computation processing unit 4 of FIG. 2A.

The data holding unit 2 includes three flip-flops FF1 to FF3 to hold three data J5, K5, M5 generated by the M(=5)^{th} αΣ modulation unit MU5. The data held by the flip-flops FF1 to FF3 are output to the first αΣ modulation unit MU1 as data J0, K0, M0 at a timing of positive edge of the next clock signal clk.

The i(i≠1)^{th} αΣ modulation unit MUi generates data based on the data generated by the i−1^{th} αΣ modulation unit MUi-1 and the most significant bit MSBi-1 of the output data Mi-1 generated by the i−1^{th} αΣ modulation unit MUi-1.

The i^{th} αΣ modulation unit MUi generates data based on the data J0, K0, M0 held in the data holding unit 2.

The αΣ modulation units MU1 to MU5 include cascade-connected sub-circuits subJ, subK, subM of the number L(=3) corresponding to the order of αΣ modulation. In the case of the αΣ modulator hating different orders, the number of αΣ modulation units merely need to be increased.

The computation processing unit 4 includes m sub-circuits subJ1 to subJ5 (hereinafter collectively referred to as sub-circuit subJ), m sub-circuits subK1 to subK5 (hereinafter collectively referred to as sub-circuit subK), and m sub-circuits subM1 to subM5 (hereinafter collectively referred to as sub-circuit subM). The sub-circuits subJ, subK, and subM are set as sub-circuit of fist stage, second stage and third stage in order.

Three clock signals clk1, clk2, clk150 are provided to the αΣ modulator 10 of FIG. 3. The clock signal clk1 is a signal which determines the timing of computation processing, and corresponds to the clock signal clk_L of FIG. 2A. The clock signal clk150 is a signal for generating data after oversampling, and corresponds to the clock signal clk_H of FIG. 2A. The clock signal clk2 has a frequency f1 same as the input data.

The sub-circuit subJ includes three input terminals input with data in0, in1, se10, an output terminal J for outputting data J, an adder ADD, and a multiplexer MUX. In the following description, the reference numerals denoted to a certain terminal is also used for the reference numerals of the signal input/output through the relevant terminal. Predetermined constants a1, −a1 are input to the multiplexer MUX, and either one is output according to the value of the data se10. The data input/output to the sub-circuit subJ are parallel data, and the bus width (number of bits) of each data line is set so that overflow does not occur.

The adder ADD adds data in0, in1, and the output data of the multiplexer MUX, and outputs from the output terminal J.

The sub-circuits subK, subM are configured similar to the sub-circuit subJ. The difference with the sub-circuit subJ lies in the constants to be input to the multiplexer MUX and the bus width of the data line.

The input data di is input to the input in0 of the sub-circuit subJ. The input data di corresponds to the input data din of FIGS. 2A and 2B.

The output J of the i−1^{th} sub-circuit subJi-1 is input to the input in1 of the i^{th} (i≠1, that is, 1≦i≦4) sub-circuit subJi. The output data Q(=J0) of the flip-flop FF1 is input to the input in0 of the sub-circuit subJ1 of the initial stage i=1.

The output data J of the sub-circuit subJ5 is input to the D terminal of the flip-flop FF1, and the clock signal clk1 is input to the clock terminal thereof.

The output J of the i−1^{th} sub-circuit subJi-1 is input to the input in2 of the i^{th} (i≠1) sub-circuit subKi. The output J of the i−1^{th} sub-circuit subKi-1 is input to the input in3 of the i^{th} (i≠1) sub-circuit subKi.

The output data Q (=J0) of the flip-flop FF1 is input to the input in2 of the sub-circuit subJ1 of the initial stage i=1. The output data Q(=K0) of the flip-flop FF2 is input to the input in3 of the sub-circuit subK1 of the initial stage i=1.

The output data J of the sub-circuit subK5 is input to the D terminal of the flip-flop FF2, and the clock signal clk1 is input to the clock terminal.

The output J of the i−1^{h} sub-circuit subKi-1 is input to the input in4 of the i^{th} (i≠1) sub-circuit subMi. The output J of the i−1^{th} sub-circuit subMi-1 is input to the input in5 of the i^{th} (i≠1) sub-circuit subMi.

The output data Q(=J0) of the flip-flop FF1 is input to the input in4 of the sub-circuit subM1 of the initial stage i=1. The output data Q(=M0) of the flip-flop FF3 is input to the input in5 of the sub-circuit subM1 of the initial stage i=1.

The output data J of the sub-circuit subM5 is input to the D terminal of the flip-flop FF3, and the clock signal clk1 is input to the clock terminal.

The following is obtained by generalizing the configuration of the sub-circuit.

The sub-circuit of the j^{th} stage included in the i^{th} αΣ modulation unit includes,

a multiplexer MUX which outputs a predetermined value corresponding to the most significant bit of the output data of the i−^{th} (m^{th} when i=1) αΣ modulation unit; and

an adder ADD which adds the output data of the sub-circuit of the j−1^{th} stage (input data when j=1), the output data of the sub-circuit of the j^{th} stage in the i−1^{th} (m^{th} when i=1) αΣ modulation unit, and the output data of the multiplexer.

The output data of the adder ADD of the sub-circuit of j (≠L)^{th} stage is input to the adder ADD of the sub-circuit of the j+1^{th} stage. The output of the adder ADD3 of the sub-circuit of the j=L (=3)^{th} stage is the output data Mi of the i^{th} αΣ modulation unit MUi.

The most significant bits of the output data M of the sub-circuits subM1 to subM5 are indicated as MSB1 to MSB5. The most significant bits MSB1 to MSB5 indicate data at each oversampled sampling point. The bit stream by αΣ modulation is generated by successively outputting the most significant bits MSB1 to MSB5.

The output data holding unit 6 includes a flip-flop FF4, a flip-flop FF5, and a flip-flop FF6.

The most significant bits MSE1 to MSB5 are input to the D terminal of the flip-flop FF4 of five bit input. The first clock signal clk1 having the first frequency f1 is input to the clock terminal of the flip-flop FF4.

The most significant bit MSBi-1 of the i−1^{th} sub-circuit subMi is commonly input to the se10 of the i^{th} (i≠1) sub-circuits subJi, subKi, subMi. The most significant bit MSB0 of the output data Q(=M0) of the flip-flop FF3 is commonly input to the se10 terminal of the i=1^{th} sub-circuits subJ1, subK1, subM1.

As described above, the computation processing unit 4 collectively generates data corresponding to five sampling timings with one computation processing in the oversampling process of n=10 times. Therefore, the αΣ modulator 10 of FIG. 3 holds the computation processing result for two rounds, and collectively outputs the data for ten sampling timings. Therefore, the flip-flop FF5 is arranged. The flip-flop FF5 delays the data latched in the flip-flop FF4 by one clock of the first clock signal clk1. The data of five bits delayed by the flip-flop FF5 and the non-delayed data of five bits output from the flip-flop FF4 are combined to generate data of ten bits. The data of ten bits is input to the D terminal of the flip-flop FF6.

The clock signal clk2 is input to the clock terminal of the flip-flop FF6. The frequency of the clock signal clk2 is equal to the frequency of the input data di. The data of ten bits is retrieved to the flip-flop FF6 for every positive edge of the clock signal clk2.

The output data generating unit 8 includes a parallel-serial conversion circuit 12, and a flip-flop FF8.

The parallel-serial conversion circuit 12 converts the output data of the flip-flop FF6 of parallel ten bits to serial data. The parallel-serial conversion circuit 12 is configured by a shift register. The data converted to the serial data is input to the D terminal of the flip-flop FF7. The clk150 is input to the clock terminal of the flip-flop FF7. The flip-flop FF7 outputs the bit stream in synchronization with the clock signal clk150.

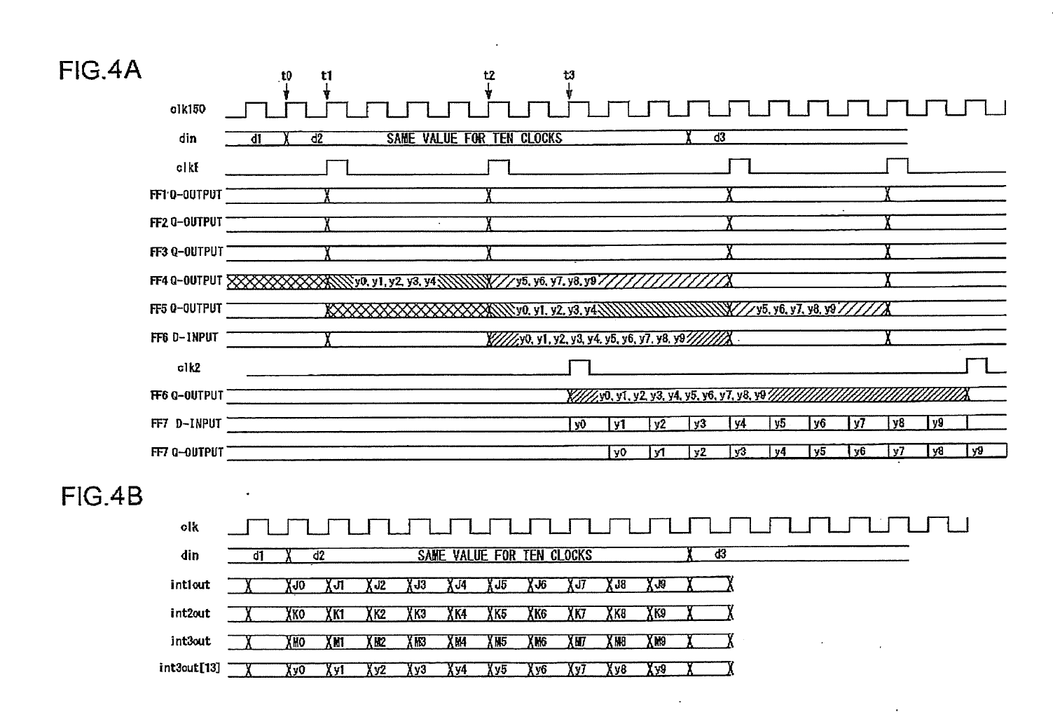

The operation of the αΣ modulator 10 of FIG. 3 configured as above will now be described. FIGS. 4A and 4B respectively show timing charts of the operation states of the αΣ modulator 10 of FIG. 3 and the αΣ modulator 500 of FIG. 1.

First, the operation of the αΣ modulator 500 of FIG. 1 will be described with reference to FIG. 4B to clarify the effects of the αΣ modulator 10 according to the present embodiment. In the αΣ modulator 500 of FIG. 1, the oversampling circuit 501 generates the input data din in synchronization with the clock signal clk having the frequency after oversampling. The value of the input data din is fixed to a constant value with respect to one input data dx.

Three flip-flops FF1 to FF3 perform computation processing for every clock signal clk, generate the output data int3out, and output int3out [13] of the most significant bit. That is, the operation frequency of the αΣ modulator 500 is the frequency after oversampling.

The operation of the αΣ modulator 10 of FIG. 3 will be described with reference to FIG. 4A. At time t0, the value of the input data din transits from d1 to d2. As a result, the output data J1 to J5 of the sub-circuits subJ1 to subJ5 are updated. The output data K1 to K5 of the sub-circuits subK1 to subK5 are updated in order based on the updated data J1 to J5. In response, the output data M1 to M5 of the sub-circuits subM1 to subM5 are updated. The data J1 to J5, K1 to K5, and M1 to M5 correspond to the output data int1out, int2out, int3out of each flip-flop FF1 to FF3 of FIG. 4B.

At time t1, the clock signal clk1 becomes high level. The phase of the clock signal clk is determined in view of the time required for executing the computation in the computation processing unit 4 and the setup time of the flip-flop. At time t1, the output data of all the sub-circuits must be defined.

When the clock signal clk1 becomes high level at time t1, the most significant bits MSB1 to MSB5 of the output data M1 to M5 of the sub-circuits subM1 to subM5 are retrieved into the flip-flop FF4 and the output y0 to y4 thereof are defined.

Furthermore, when the clock signal clk1 becomes high level at time t1, the output data J5, K5, M5 of the fifth sub-circuits subJ5, subK5, subM5 are retrieved into the flip-flops FF1 to FF3, and the output data J0, J0, M0 of the flip-flops FF1 to FF3 are updated. As a result, the output data of the sub-circuits in the computation processing unit 4 are again updated.

At time t2, the clock signal clk1 becomes high level, and the data y5 to y9 at the next five sampling timings are latched to the flip-flop FF4.

At the following time t3, the clock signal clk2 becomes high level, and the data at ten sampling timings are latched to the flip-flop FF6. The data y0 to y9 latched to the flip-flop FF6 are output as bit stream in synchronization with the clock signal clk150.

Thus, in the αΣ modulator 10 according to the present embodiment, the computation processing unit 4 updates the data for every positive edge of the clock signal clk1. Therefore, the operation frequency can be set low compared to the αΣ modulator 500 of FIG. 1, and furthermore, the power consumption can be reduced.

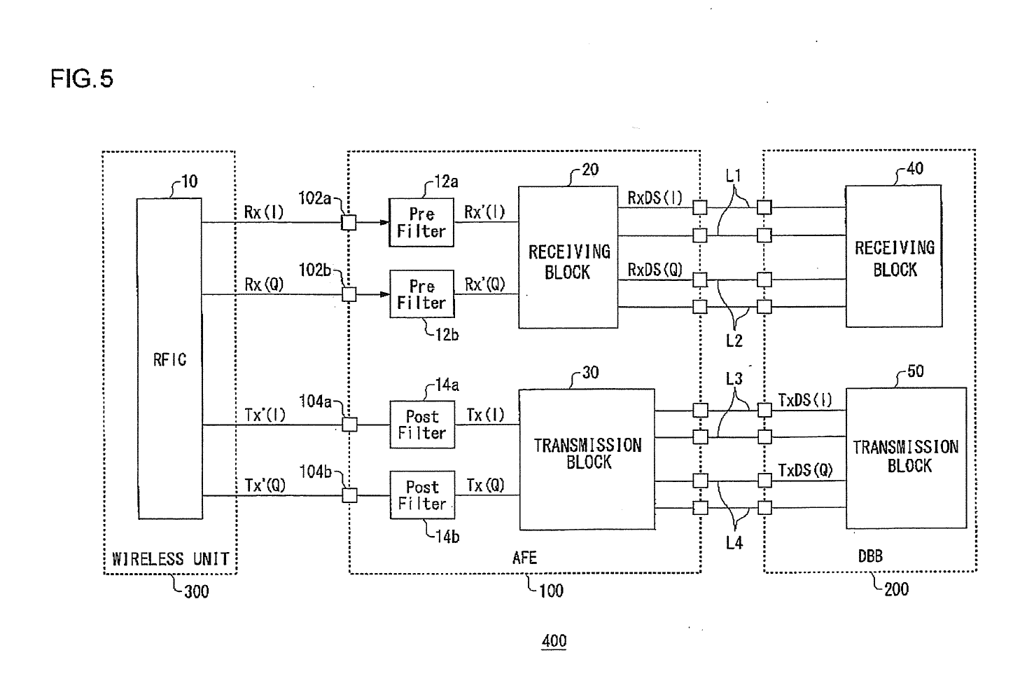

FIG. 5 is a circuit diagram showing a configuration of electronic equipment using the αΣ modulator 10 of FIG. 2. The electronic equipment is a battery driven device such as portable telephone terminal, portable audio players and the like. FIG. 5 is a block diagram showing a configuration of the electronic equipment. In the present embodiment, description is made with the electronic equipment 400 as the portable telephone terminal by way of example.

The electronic equipment 400 includes an analog front end circuit 100, a baseband circuit 200, and a wireless unit 300. The analog front end circuit 100 is a circuit block for performing transmission and reception of data between the baseband circuit 200 and the wireless unit 300, and includes a receiving block 20 and a transmission block 30, as well as pre-filters 12a, 12b, and post-filters 14a, 14b. The baseband circuit 200 also includes a receiving block 40 and a transmission block 50. The receiving block 20 of the analog front end circuit 100 and the receiving block 40 of the baseband circuit 200 form a pair and transmit/receive data. The transmission block 30 of the analog front end circuit 100 and the transmission block 50 of the baseband circuit 200 form a pair and transmit/receive data.

The wireless unit 300 includes an amplifier circuit such as RFIC 10 and power amplifier (not shown), and an antenna. The RFIC 10 amplifies a RF receiving signal received by the antenna (not shown), and frequency-converts the RF receiving signal to an intermediate frequency (hereinafter referred to as IF frequency). The IF receiving signal converted to the IF frequency is amplified by an automatic gain control (AGC) amplifier, and then decomposed into the I component and the Q component by orthogonal detection, and output as receiving signals Rx(I) and Rx(Q). The receiving signals Rx(I) and Rx(Q) are respectively input to input terminals 102a, 102b of the analog front end circuit 100, and band limited by the pre-filters 12a, 12b.

The receiving block 20 of the analog front end circuit 100 analog-digital-converts the receiving signals Rx′ (I) and Rx′ (Q), performs αΣ modulation to convert the signals to bit stream signals, and then converts the resultant to low voltage differential signals RxDS(I) and RxDS(Q). The low voltage differential signals RxDS(I) and RxDS(Q) are output to the baseband circuit 200 via differential signal lines L1 and L2,

The baseband circuit 200 Σα-demodulates the bit stream signal input as low voltage differential signals RxDS(I) and RxDS (Q). Subsequently, back diffusion is performed by means of the demodulator arranged inside to reproduce the data.

The transmission block 50 of the baseband circuit 200 performs data modulation by means of the modulator arranged inside, and mapping of the I component and the Q component, and outputs a diffused chip data column. The chip data column is converted to a bit stream signal through Σα modulation, converted to the low voltage differential signals TxDS (I) and TxDS (Q), and output to the analog front end circuit 100 via differential signal lines L3, L4. The transmission block 30 of the analog front end circuit 100 Σα-demodulates the bit stream signal input as the low voltage differential signals TxDS(I) and TxDS(Q), performs digital-analog conversion, and outputs the resultant as transmission signals Tx(I) and Tx(Q) to the wireless unit 300.

The digital-analog-converted transmission signals Tx(I) and Tx(Q) are band-limited by the analog filter (not shown) and the post-filters 14a, 14b and output to the RFIC 10 as Tx′ (I) and Tx′ (Q).

The RFIC 10 orthogonally modulates the transmission signals Tx′ (I) and Tx′ (Q) at the IF frequency, and converts the signals to an RF signal of 2 GHz band. The RF signal is amplified in the power amplifier (not shown) of post stage and transmitted from the antenna as electric wave.

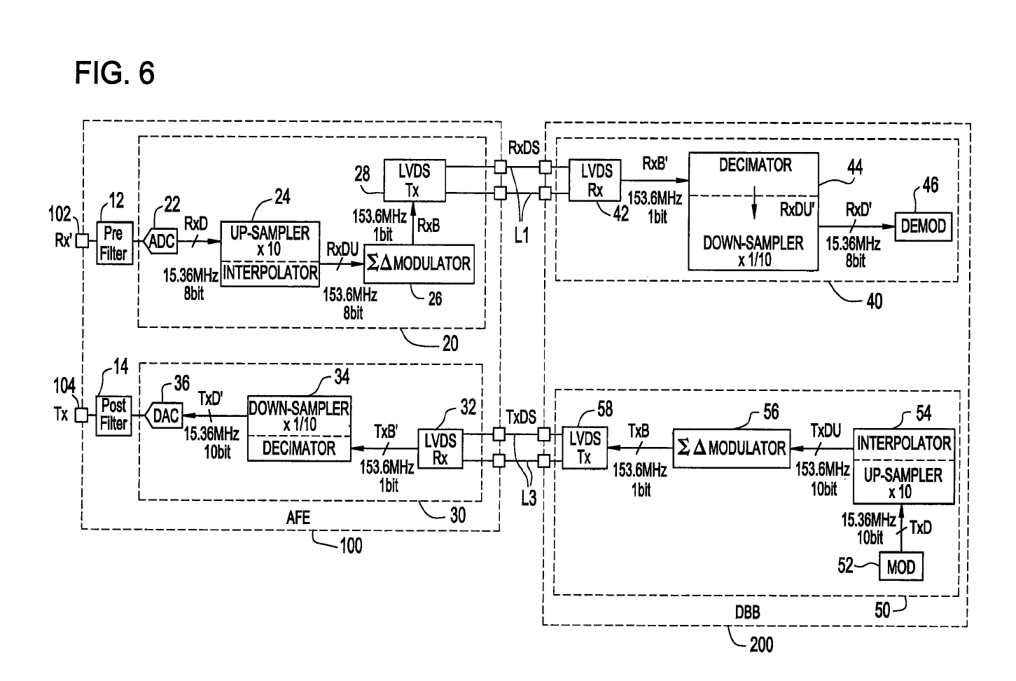

The inner configuration of the analog front end circuit 100 and the baseband circuit 200 will now be described in detail. FIG. 6 is a block diagram showing an inner configuration of the analog front end circuit 100 and the baseband circuit 200 of FIG. 5. Only one of the I component or the Q component is shown in FIG. 6 for clarification, but both I and Q components are mounted in the actual circuit. For simplification, reference numerals (I) and (Q) denoted on signals to distinguish the I component and the Q component are not described.

As described above, the analog front end circuit 100 is divided into the receiving block 20 and the transmission block 30, and the baseband circuit 200 is divided into the receiving block 40 and the transmission block 50. First, the configuration of the receiving block 20 of the analog front end circuit 100 and the receiving block 40 of the baseband circuit 200 will be described.

The receiving block 20 of the analog front end circuit 100 includes an analog-digital converter 22, an interpolator 24, a Σα modulator 26, and a low voltage differential signal transmitter (hereinafter referred to as LVDS transmitter) 28.

The analog-digital converter 22 analog-digital-converts the analog receiving signal Rx′ output from the wireless unit 300 and input to the input terminal 102 at resolution m of eight bits and reference sampling rate fs of 15.36 MHz.

The interpolator 24 is a so-called interpolation filter which up-samples the digital signal RxD output from the analog-digital converter 22 at a frequency of ten times the reference sampling rate fs, and performs data interpolation. The digital signal RxDU of sampling rate fs′ of 153.6 MHz and resolution of eight bits is output from the interpolator 24.

The Σα modulator 26 Σα-modulates the digital signal RxDU output from the interpolator 24 at high order (greater than or equal to second order). In the present embodiment, the Σα modulator 26 is a Σα modulator of fourth order. The lower limit of the order of the Σα modulator 26 is desirably greater than or equal to third order in view of accuracy of the signal. Furthermore, the upper limit of the order of the Σα modulator 26 is mainly subjected to limitation from the circuit area, and is desirably lower than or equal to fifth order. The order of the Σα modulator 26 may be appropriately selected between the third order and the fifth order according to the up-sampling rate fs′ /fs and the accuracy of the desired signal.

The Σα-modulated bit stream signal RxB of one bit and 153.6 MHz is output from the Σα modulator 26. The bit stream signal RxB is input to the LVDS transmitter 28. The LVDS transmitter 28 converts the bit stream signal RxB to a low voltage differential signal RxDS, and transmits the low voltage differential signal RxDS to the baseband circuit 200 via the differential signal line L1.

The configuration of the receiving block 40 of the baseband circuit 200 will now be described. The receiving block 40 of the baseband circuit 200 includes a low voltage differential signal receiver (hereinafter referred to as LVDS receiver 42), a decimation circuit 44, and a demodulator 46.

The LVDS receiver 42 receives the Σα-modulated low voltage differential signal RxDS of one bit output from the analog front end circuit 100 via the differential signal line L1, and converts the low voltage differential signal RxDS to a bit stream signal RxB′.

The decimation circuit 44 is a so-called decimation filter which accumulates the bit stream signal RxB′ output from the LVDS receiver 42, and down-samples the signal at the reference sampling rate fs of 15.36 MHz. The output signal RxD′ of the decimation circuit 44 becomes a digital signal of eight bits and 15.36 MHz. The demodulator 46 demodulates the output signal RxD′ of the decimation circuit 44 through a predetermined method.

The configuration of the transmission block 50 of the baseband circuit 200 and the transmission block 30 of the analog front end circuit 100 will now be described.

The transmission block 50 of the baseband circuit 200 includes a modulator 52, an interpolator 54, a Σα modulator 56, and a LVDS transmitter 5B.

The modulator 52 outputs a digital transmission signal TxD data-modulated through a predetermined method at resolution of ten bits and reference sampling rate fs of 15.36 MHz. The digital transmission signal TxD output from the modulator 52 is input to the interpolator 54.

The interpolator 54 up-samples and interpolates the digital transmission signal TxD, and converts the digital transmission signal TxD to a digital transmission signal TxDU of 153.6 MHz and ten bits. The Σα modulator 56 Σα-modulates the digital transmission signal TxDU output from the interpolator 54, and converts the signal to a bit stream signal TxB. The order of the Σα modulator 56 is desirably greater than or equal to the third order, similar to the Σα modulator 26 of the analog front end circuit 100.

The LVDS transmitter 58 converts the bit stream signal TxB output from the Σα modulator 56 to a low voltage differential signal TxDS, and outputs the low voltage differential signal TxDS to the analog front end circuit 100 via the differential signal line L3.

The configuration of the transmission block 30 of the analog front end circuit 100 will now be described. The transmission block 30 of the analog front end circuit 100 includes a LVDS receiver 32, a decimation circuit 34, and a digital-analog converter 36.

The LVDS receiver 32 receives the low voltage differential signal TxDS output from the baseband circuit 200, and converts the low voltage differential signal TxDS to a bit stream signal TxB′. The decimation circuit 34 accumulates and down-samples the bit stream signal TxB′ received by the LVDS receiver 32. The output signal TxD′ of the decimation circuit 34 is a digital signal of eight bits and 15.36MHz.

The digital-analog converter 36 digital-analog-converts the output signal TxD′ of the decimation circuit 34, and outputs an analog transmission signal Tx to the wireless unit 300 from the output terminal 104.

According to the transmission block 50 of the baseband circuit 200 and the transmission block 30 of the analog front end circuit 100 configured as above, the digital transmission signal TxD generated in the baseband circuit 200 is converted to the Σα-modulated digital signal of one bit at high order, and transmitted to the analog front end circuit 100, similar to the receiving block 20 and the receiving block 40 described above. As a result, the number of signal lines connecting the analog front end circuit 100, the baseband circuit 200, and the wireless unit 300 can be reduced. Since precise synchronization process between the analog front end circuit 100 and the baseband circuit 200 is not necessary, the circuit can be simplified.

The Σα modulator 10 according to the embodiment can be used as a circuit corresponding to the functions of the interpolator 24 and the Σα modulator 26 of FIG. 6. Similarly, the interpolator 54 and the Σα modulator 56 of FIG. 6 may be configured with the Σα modulator 10 of FIG. 3.

Since power consumption can be reduced by using the Σα modulator 10 of FIG. 3 in the electronic equipment 400, the battery run time can be extended.

The above embodiments are illustrative, and it should be recognized by those skilled in the art that various variants can be made on combination of each component and each processing process, and that such variants are also encompassed in the scope of the present invention.

Various variants can be contrived for the configuration of the Σα modulator 10 in the embodiment, and such variants are also encompassed in the scope of the present invention. For instance, the number of Σα modulation units MU can be changed according to the number m of data at the sampling timing to be simultaneously calculated, and the number (number of stages) of sub-circuits in the Σα modulation unit MU can be changed according to the order of the Σα modulation. Furthermore, when data at a plurality of past sampling timings is required for the generation of data at a certain sampling timing, the f lip-flop in the data holding unit 2 of FIG. 2 may be arranged for every Σα, modulation unit which generates the data at the necessary sampling timing.

In the embodiment, signal transmission by differential signal has been described as an application of the Σα modulator 10 of FIG. 3, but the present invention is not limited thereto, and is also suitably used for Σα modulation in digital audio signal processing.

In the present embodiment, the Σα modulation has been described for the digital signal processing, but the present invention i s not limited thereto, and the process thereof is not particularly limited. Therefore, application can be made to various digital signal processing circuits abstracted in the block diagram of FIG. 2A.

While the preferred embodiments of the present invention have been described, such description is for illustrative purposes only, and it is to be understood that changes and variations may be made without departing from the spirit or scope of the appended claims.

What is claimed is:

1. A digital signal processing circuit which performs a predetermined computation processing on input data sequentially input at a first frequency, and generates output data of a second frequency oversampled to n times (n is an integer greater than or equal to 2); the digital signal processing circuit comprising:
a computation processing unit which collectively computes m (m is 2≦m≦n) successive output data in the output data at n sampling timings after oversampling;
a data holding unit which holds data at a predetermined sampling timing in the data generated in the computation processing unit; and
a data output unit which sequentially outputs the m output data obtained by the computation processing unit according to a second frequency; wherein
the computation processing unit generates m successive output data after the predetermined sampling timing based on the data at the predetermined sampling timing held in the data holding unit and the input data.

2. The digital signal processing circuit according to claim 1, wherein
m is a divisor of n.

3. The digital signal processing circuit according to claim 2, wherein
the data holding unit includes a flip-flop input with a clock signal having a frequency of n/m times the first frequency.

4. The digital signal processing circuit according to claim 1, wherein
the computation processing circuit includes m cascade-connected computation units,
an i^{th} (i≠1) computation unit performs computation processing using data generated by an i−1^{th} computation unit;
a first computation unit performs computation processing using the data held in the data holding unit; and
the data holding unit holds the data generated by an m^{th} computation unit.

5. The digital signal processing circuit according to claim 2, wherein
the data output unit includes an output data holding unit which holds successive data worth (n/m) times in the output data at the m successive sampling timings generated from the m computation units when m≠n, and sequentially outputs the data held in the output data holding unit according to the second frequency.

6. The digital signal processing circuit according to claim 1, wherein
the predetermined process is a αΣ modulation.

7. The digital signal processing circuit according to claim 1, being monolithically integrated on one semiconductor substrate.

8. Electronic equipment comprising;
a battery; and
the digital signal processing circuit according to claim 1 which receives power supply from the battery.

9. A αΣ modulator which αΣ-modulates input data sequentially input at a first frequency and generates output data of a second frequency oversampled to n times (n is an integer greater than or equal to 2); the αΣ modulator comprising:
m cascade-connected αΣ modulation units which respectively generate m (m is 2≦m≦n) successive output data in the output data at n sampling timings after oversampling; and
a data holding unit which holds data generated by the m^{th} αΣ modulation unit; wherein
an i^{th} (i≠1) αΣ nodulation unit generates data based on data generated by an i−1^{th} αΣ modulation unit and a most significant bit of the output data generated by the i−1^{th} αΣ modulation unit; and
a first αΣ modulation unit generates data based on the data held in the data holding unit.

10. The αΣ modulator according to claim 9, wherein
the αΣ modulation unit includes cascade-connected sub-circuits of L number corresponding to an order of the αΣ modulation;
the sub-circuit of j^{th} stage arranged in the i^{th} αΣ modulation unit includes,
a multiplexer which outputs a predetermined value corresponding to the most significant bit of the output data of the i−1^{th} (m^{th} when i=1) αΣ modulation unit, and
an adder which adds the output data of the sub-circuit of the j−1^{th} stage (the input data when j=1), the output data of the sub-circuit of the j^{th} stage in the i−1^{th} (m^{th} when i=1) αΣ modulation unit, and the output data of the multiplexer;
the output data of the adder of the sub-circuit of j (≠L)^{th} stage is input to the adder of the sub-circuit of j+1th stage, and the output of the adder of the sub-circuit of j (=L)^{th} stage is the output data of the i^{th} αΣ modulation unit; and
the data holding unit holds the output data of each sub-circuit contained in the m^{th} αΣ modulation unit.

11. The αΣ modulator according to claim 10, wherein
the data holding unit includes a flip-flop input with a clock signal having a frequency of n/m times the first frequency.

12. The αΣ modulator according to claim 9, being monolithically integrated on one semiconductor substrate.

13. An electronic circuit comprising:
a battery; and
the αΣ modulator according to claim 9 which receives power supply from the battery.
